(19) United States
(12) Patent Application Publication
(10) Pub. No.: US 2026/0214868 A1
(43) Pub. Date: Jul. 23, 2026

(54) HEAT SINK WITH FINS AND MULTIPLE MATERIALS

(71) Applicant: DENSO International America, Inc., Southfield, MI (US)

(72) Inventors: Siddharth DASGUPTA, Windsor (CA); Makoto SAIZEN, Novi, MI (US)

(21) Appl. No.: 19/055,081

(22) Filed: Feb. 17, 2025

Related U.S. Application Data
(60) Provisional application No. 63/748,489, filed on Jan. 23, 2025.

(51) Int. Cl. H05K 7/20

(52) U.S. Cl. CPC H05K 7/209

(57) ABSTRACT

A heat sink for a power inverter assembly in a motor vehicle comprises a base having a lower surface and an opposing upper surface. The lower surface contacts (indirectly or directly) a heat-generating device. A plurality of fins extend from the upper surface of the base. Some of the fins are aligned with the heat-generating device, while others are not. The fins can have different thermal conductivities. For example, each fin in a first subset of the plurality of fins is made of a first material and a second material, wherein the first material has a higher thermal conductivity than the second material. Each fin in a second subset of the plurality of fins is made of the second material and is substantially free of the first material.

### CROSS-REFERENCE TO RELATED APPLICATION

This application claim the benefit of U.S. Provisional Application No. 63/748,489 filed Jan. 23, 2025, the entire disclosure of which is incorporated by reference herein.

### TECHNICAL FIELD

The present disclosure relates to a non-homogeneous heat sink having material(s) of higher thermal conductivity in select regions of the heat sink.

### BACKGROUND

The performance, lifespan, and safety of many electrical components are dependent on the temperature at which the electrical components operate and a build-up of heat can negatively affect these elements. The temperature of the electrical component may be affected by heat generated from the electrical component or its surrounding environment. Heat sinks are used to dissipate heat from electrical components or other heat-generating devices and prevent the negative effects from a build-up of heat. Some heat sinks use pin fins that extend outward from a base that is in thermal communication with the electrical component. As fluids (e.g., air, water, or the like) flow along the heat sink in between the pin fins, the pin fins transfer the heat from the electrical component to the fluid, cooling the electrical component.

### SUMMARY

In an embodiment, a heat sink for a power inverter assembly in a motor vehicle, comprises: a base having a lower surface and an opposing upper surface, wherein the lower surface contacts a heat-generating device; and a plurality of fins extending from the upper surface of the base; wherein each fin in a first subset of the plurality of fins is made of a first material and a second material, wherein the first material has a higher thermal conductivity than the second material; and wherein each fin in a second subset of the plurality of fins is made of the second material and is substantially free of the first material.

In another embodiment, a heat sink for a power inverter assembly in a motor vehicle comprises: a base having a lower surface and an opposing upper surface; and a plurality of fins extending from the upper surface of the base, wherein the plurality of fins includes a first subset of fins and a second subset of fins; wherein each fin in the first subset of fins is made of a first material and a second material, wherein the first material has a higher thermal conductivity than the second material; and wherein each fin in the second subset of fins is made of the second material and is substantially free of the first material.

In an embodiment, power inverter assembly comprises: a heat-generating device; and a heat sink having: a base having a lower surface and an opposing upper surface, wherein a region of the lower surface contacts the heat-generating device; and a plurality of fins extending from the upper surface of the base, wherein a first subset of fins are aligned with the region of the lower surface, and wherein a second subset of fins are not aligned with the region of the lower surface; wherein at least some of the fins within the first subset of fins are made of a first material and a second material, wherein the first material has a higher thermal conductivity than the second material; wherein at least some of the fins within the second subset of fins are made of the second material and are substantially free of the first material; and wherein a portion of the base aligned with the region of the lower surface is made of the second material and is substantially free of the first material.

### BRIEF DESCRIPTION OF THE DRAWINGS

FIG. 1A is a perspective view of a heat sink, according to an embodiment.

FIG. 1B is a perspective view of an opposite side of the heat sink of FIG. 1A, according to an embodiment.

FIG. 2 is a cross-sectional view of a heat sink with a non-homogeneous (e.g., heterogeneous) makeup including a first material having a first thermal conductivity and a second material having a second thermal conductivity, according to an embodiment.

FIGS. 3A-3C are examples of various placements of the higher thermal conductivity material within the heat sink, according to embodiments.

FIG. 4 is a top view of a heat sink according to an embodiment.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

An inverter card is an electronic component used to convert direct current (DC) to alternating current (AC), typically in applications such as powering AC motors, lighting, and other devices from a DC source. In an automotive setting, power inverter assemblies are critical components in automotive electric drive systems, converting DC from a battery into AC to drive an electric motor. These inverters utilize power cards, which contain semiconductor switches such as insulated-gate bipolar transistors (IGBTs) or metal-oxide-semiconductor field-effect transistors (MOSFETs) to regulate power flow. During operation, these semiconductor components generate significant amounts of heat, necessitating efficient cooling to maintain performance and reliability.

To manage thermal loads, inverter assemblies are commonly equipped with heat exchangers or heat sinks, typically made from thermally conductive metals such as aluminum or copper. These heat sinks are often integrated with a liquid cooling system, where a coolant fluid flows through the assembly to absorb and dissipate heat. However, a common problem with heat sinks, particularly in liquid-cooled systems, is uneven cooling distribution due to temperature gradients in the coolant as it flows from the inlet to the outlet. When the coolant first enters the heat sink, it is at its lowest temperature, allowing for efficient heat transfer from the components to the coolant. However, as the coolant absorbs heat along its path, it gradually warms up, decreasing its ability to absorb additional heat near the outlet. This results in uneven cooling efficiency, where components near the coolant inlet receive the most effective cooling, while those closer to the outlet experience reduced cooling efficiency. This temperature gradient can lead to localized hot spots, making it challenging to maintain consistent cooling performance across all components. Optimizing coolant flow and temperature regulation is essential in managing this phenomenon, especially in high-power applications where thermal balance is critical.

The present disclosure addresses this problem by introducing a non-homogeneous heat sink design in which different materials are selectively used to optimize thermal management. Specifically, regions of the heat sink can be made from a material having a first thermal conductivity, while other regions of the heat sink can be made from another material having a second thermal conductivity. More specifically, in embodiments, regions of the heat sink that experience the highest thermal loads—such as areas near the coolant outlet—are constructed from a material with higher thermal conductivity (e.g., copper or a copper-aluminum composite), while regions that experience lower thermal loads, such as the coolant inlet or certain fin structures, can be made from lower thermal conductivity materials (e.g., tungsten or titanium alloys).

This strategic material placement enhances overall cooling performance by improving heat dissipation in the most thermally stressed regions while maintaining cost, weight, and manufacturing efficiency. Additionally, this design enables more uniform temperature distribution across the power cards, reducing the risk of thermal hotspots, improving component longevity, and optimizing inverter efficiency in high-power automotive applications.

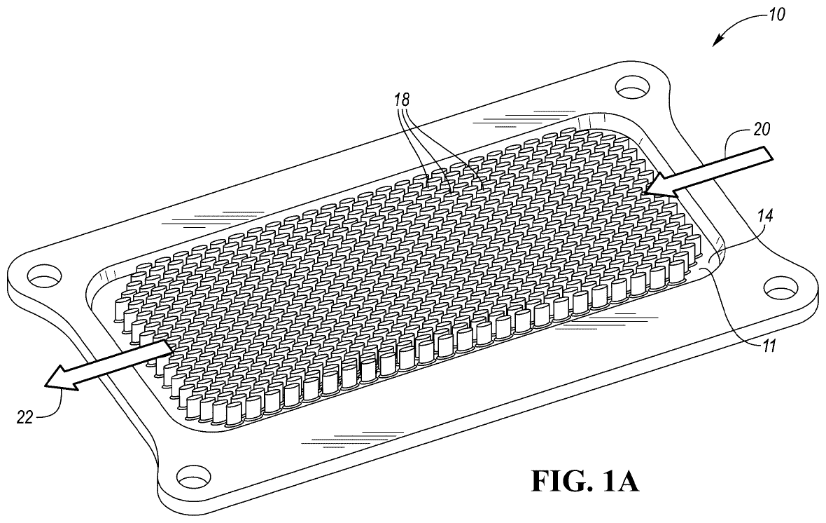

As shown in FIGS. 1A-1B, according to the prior art, a heat sink 10 is shown for dissipating heat from a device capable of generating heat, such an electrical or computer component, an inverter card, or the like. Here, three separate power cards 12 are shown. It should be understood that “power cards” can generally refer to any circuit board that manages or processes power within a system, and that may handle various power-related tasks such as voltage conversion, regulation, distribution, and protection, and DC-to-AC conversion (i.e., inverter card). The power cards 12 may also not necessarily be designed for DC-to-AC conversion, but instead may handle AC-DC conversion, DC-DC conversion, or simply regulate power for different parts of a system. In general, an inverter card can be considered a type of power card due to its power-handling role, but the power card is a broader term intended to refer to any circuit board that manages or processes power and generates heat as a result.

As shown, the heat sink 10 has a base 11 with an upper surface 14 and an opposing lower surface 16. The power card(s) 12 are in direct contact with the lower surface 16. The heat sink 10 also has plurality of fins 18 (e.g., pins, projections, protrusions, or the like) that extend from the base 11 and are configured to increase the surface area of the heat sink for more effective heat transfer. As shown, the fins 18 can extend from the upper surface 14 of the heat sink 10.

Assume an inlet is generally aligned with the right-hand side of the heat sink (as shown by arrow 20) so that an inlet of fluid (e.g., air, liquid, etc.) engages with the fins on the right-hand side of the heat sink, and the fluid travels from right-to-left across the heat sink and between the fins 18, whereupon the fluid exits an outlet of the heat sink (as shown by arrow 22) near the left-hand side of the heat sink 10. As explained above, the fluid becomes warmer as the fluid travels from right-to-left across the heat sink 10. This means that less effective heat transfer takes place on the left-hand side of the heat sink, which can lead to the correspondingly aligned power cards on the left-hand side being subject to less effective heat transfer. In other words, the power cards 12 on the left (closer to the outlet) of the heat sink might not be cooled as effectively as the power cards on the right (closer to the inlet) of the heat sink.

Of course directional terms such as “upper” and “lower” are relative and refer to the orientation shown in the Figures, and is not meant to be limiting on this disclosure unless the context dictates otherwise. For example, in other embodiments, the heat sink is oriented such that the fins 18 extend from lower surface thereof, and the power cards 12 are in contact with the upper surface of the heat sink.

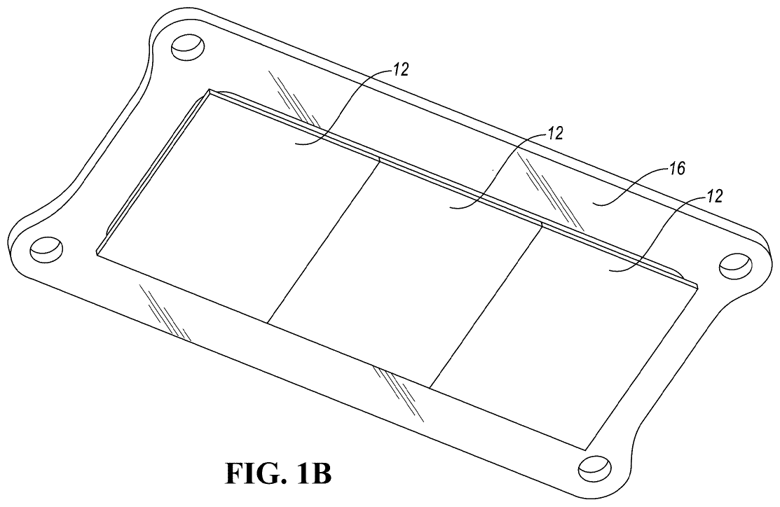

FIG. 2 illustrates a heat sink 30 with a non-homogeneous (e.g., heterogeneous) makeup, according to an embodiment. Similar to FIGS. 1A-1B, the heat sink 30 has a base 32 having an upper surface 34 and a lower surface 36, with fins 38 extending from the upper surface 34 of the base 32. Here, the heat sink 30 is made of at least two separate and distinct materials: a first material 40 having a first thermal conductivity and a second material 42 having a second thermal conductivity. The first material 40 has a higher thermal conductivity than the second material 42.

In embodiments, the first material 40 can be one or more of the following materials: copper, aluminum, copper-aluminum composite, silver, graphite-based composites, or diamond composites. In embodiments, the first material can have a thermal conductivity of greater than 200 W/mK. For example, aluminum has a thermal conductivity of about 205 W/mK, and copper has a thermal conductivity of about 385 W/mK. Diamond composites can have a thermal conductivity of even greater, such as at or near 1000 W/mK or greater.

In embodiments, the second material 42 can be one or more of the following materials: titanium, tungsten, beryllium, stainless steel, or a ceramic material (e.g., aluminum nitride, silicon carbide, zirconia, etc.). Aluminum nitride and silicon carbide can be particularly suitable because they provide moderate thermal conductivity while also being electrically insulating, which is an advantage in power electronics. In embodiments, the second material can have a thermal conductivity in the range of 150-300 W/mK.

As FIG. 2 illustrates, a first region of the heat sink can include the first material 40 with the higher thermal conductivity, and a second region of the heat sink can include the second material 42 with the lower thermal conductivity. The first material 40 with the higher thermal conductivity can be strategically placed in order to improve overall cooling performance by improving heat dissipation in the most thermally stressed regions while maintaining cost, weight, and manufacturing efficiency of the heat sink 30.

Here, in the embodiment of FIG. 2, the first material 40 is located along or within the base 32 of the heat sink 30, and not fins 38. In embodiments, the entire base 32 (i.e., from the upper surface 34 to the lower surface 36) is made of the first material, while the entire fins 36 are made of the second material. In other embodiments, only a portion of the base 32 includes the first material 40. For example, the first material 40 may be located within only a lower section of the base such that the first material 40 defines the lower surface 36 but not the upper surface 34 of the heat sink 30. Further, in some embodiments, the first material 40 may be located only within a laterally-interior section of the base 32 (e.g., not extending all the way from side to side of the base). In some embodiments, the first material 40 is located in areas that are in direct contact or vertically-aligned with the heat-generating components such as power cards 12.

As explained above, the strategic placement of the first material 40 (higher thermal conductivity) and the second material 42 (lower thermal conductivity) within the heat sink 30 enhances thermal management by directing heat dissipation to the most critical areas while optimizing weight, cost, and efficiency. Since the coolant absorbs heat as it flows through the heat sink, its temperature increases along the flow path, reducing its ability to extract heat effectively near the outlet. By incorporating the first material 40 in regions where heat transfer is weakest—such as near the coolant outlet or directly above (or directly beneath) high-power components—the design ensures more efficient heat dissipation in areas prone to thermal buildup. Meanwhile, using the second material 42 in regions with lower thermal demand—such as near the coolant inlet or in less heat-intensive structures like certain fins—reduces unnecessary heat spreading, controls thermal gradients, and can provide structural or electrical insulation benefits. This targeted material distribution promotes a more uniform temperature profile across the heat sink, improving overall cooling performance and enhancing the reliability and longevity of the power inverter assembly.

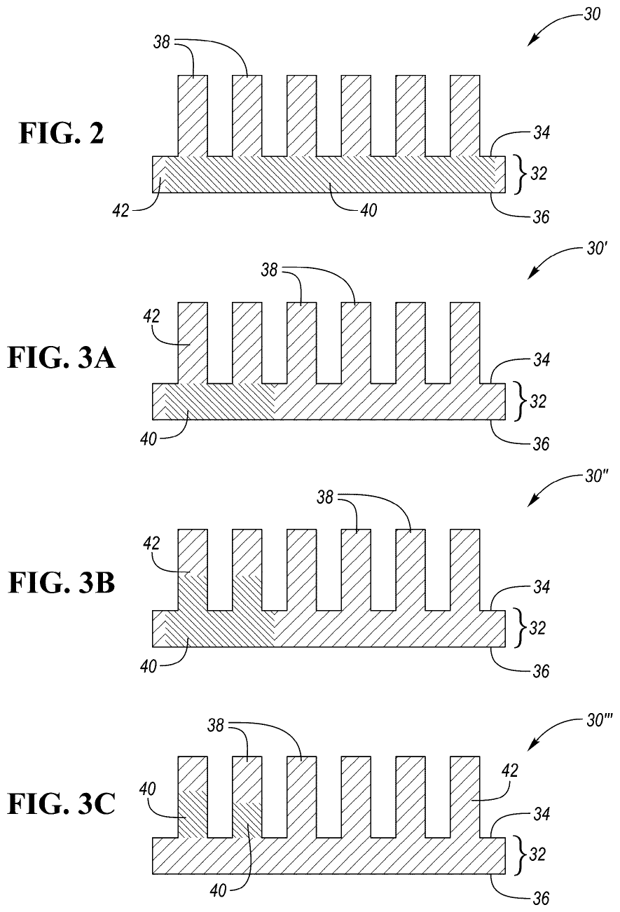

FIGS. 3A-3C illustrate additional embodiments of strategic location of the first material within the heat sink 30. Referring to FIG. 3A, this embodiment is similar to the one illustrated in FIG. 2 in that the first material 40 is located only in the base 32 and not within the fins 38. Further, in this embodiment, the first material 40 may be located only at or near the outlet of the heat sink (see arrow 22 in FIG. 1A). In other words, if the fluid flows from right to left in the view shown in FIG. 3A, the first material 40 can make up at least a portion of the base 40 near the left-hand side of the base 40.

The first material 40 may extend from the lower surface 36 to the upper surface 34 of the base 32. However, in other embodiments, the first material 40 extends from the lower surface 36 and only partially toward the upper surface 34. In other embodiments, the first material 40 extends from the upper surface 34 and only partially toward the lower surface 36. The first material 40 can be embedded in the second material within the base 32.

FIG. 3A illustrates an embodiment of a heat sink 30′ wherein the first material 40 is embedded within a portion of the base 32, specifically near one end of the heat sink. The second material 42 forms the remainder of the heat sink, including the fins 38 and the remaining portion of the base 32. This configuration positions the first material 40 in a localized region where higher heat dissipation is required, such as near a heat source (e.g., pin card 12) or at the coolant outlet. By concentrating the first material 40 in critical areas, heat is efficiently conducted away from high-temperature regions, thereby preventing localized hotspots in the base 32. The first material 40, having a higher thermal conductivity than the second material 42, facilitates the even distribution of heat across the base 32 before it is transferred to the fins 38. This design optimizes material usage, as only the regions requiring enhanced thermal conductivity incorporate the first material 40, thereby reducing both cost and weight. In alternative embodiments, the first material 40 may be positioned near multiple high-temperature regions rather than a single (lateral) side of the base 32. Additionally, rather than being embedded within the base 32, the first material 40 may be applied as a thin layer or coating along the upper surface 34. In further variations, the first material 40 may extend partially into the fins 38 to enhance heat transfer from the base 32 into the cooling structures.

FIG. 3B illustrates an alternative configuration of a heat sink 30″ in which the first material 40 is incorporated into both the base 32 and the lower sections of the fins 38. In this embodiment, the first material 40 is distributed across a larger surface area of the heat sink 30″ than the previous embodiment, while the second material 42 forms the upper portion of the fins 38 and the remaining portions of the base 32. This configuration facilitates efficient heat transfer from the base 32 into the fins 38, thereby enhancing dissipation into the surrounding environment. By limiting the first material 40 to the lower portion of the fins 38, the design maintains high thermal conductivity where it is most needed while retaining the mechanical and cost advantages of the second material 42. Additionally, this arrangement can ensure a controlled temperature gradient within the heat sink 30″, thereby preventing excessive heat buildup at the base 32 while allowing for effective convective cooling through the fins 38.

In alternative embodiments similar to FIG. 3B, the first material 40 may extend further up the fins 38 (e.g. further away from upper surface 34 that what is illustrated) if greater heat dissipation is required in those regions. In another variation, different portions of the fins 38 may incorporate varying ratios of the first material 40 and second material 42 to further optimize thermal performance. In yet another alternative, the first material 40 may be selectively applied to the base 32 beneath heat-generating components, while fins 38 that are not directly beneath heat-generating components remain composed primarily or entirely of the second material 42. In yet another embodiment, the first material 40 may be located in a portion of the base 32 that is not aligned with the fins 38 that have the first material 40. In other words, the first material 40 may be present in a portion of some of the fins 38, but also in a portion of the base 32 that is not aligned with those fins 38.

FIG. 3C illustrates another alternative embodiment of a heat sink 30′″ in which the base 32 is made primarily or entirely of the second material 42, while the first material 40 extends from the upper surface 34 of the base and partially into selected fins 38. Unlike the embodiment of FIG. 3B where the first material 40 is present in the base 30, here the first material 40 may not extend below the upper surface of the base 34. In other words, the first material 40 may be located entirely within the fins 38. This targeted distribution enhances cooling efficiency in regions experiencing higher thermal loads, such as select fins 38 that may be located directly above (or directly beneath) heat-generating components, or select fins that are located near or adjacent the outlet of the heat sink 30′″. The second material 42 in the remaining fins may provide structural reinforcement, weight reduction, or electrical insulation benefits. This design ensures a balance between thermal performance and cost efficiency, as the first material 40 is used only where necessary.

In alternative embodiments, the first material 40 may be positioned in alternating fins 38 to create a thermally optimized pattern. Additionally, the overall amount (e.g., height, width, or depth) of the first material 40 present in the fins 38 may vary depending on expected heat loads, with some fins 38 incorporating a greater proportion of the first material 40 than others. In further variations, the first material 40 may be combined with surface treatments or coatings to enhance heat dissipation efficiency further.

Beyond the specific configurations illustrated in FIGS. 3A-3C, additional alternative embodiments may be employed depending on cooling requirements and manufacturing constraints. In one embodiment, the heat sink 30 may feature a gradient composition, wherein the transition between the first material 40 and the second material 42 is continuous rather than discrete, thereby creating a gradual shift from high thermal conductivity to lower thermal conductivity. In another embodiment, the heat sink 30 may be constructed using a modular design, allowing different regions of the heat sink 30 to be configured with interchangeable first material 40 and second material 42 segments, thereby providing customized thermal performance. In yet another variation, instead of embedding the first material 40 within the base 32 or fins 38 (or having the entire base and/or fins made of the first material), a high-conductivity coating may be applied to selected surfaces to enhance heat transfer while preserving the structural benefits of the second material 42. In other words, the first material 40 may be a film or coating placed on the outside of the second material 42. Additionally, advanced manufacturing techniques such as additive manufacturing may be used to fabricate the heat sink 30 with intricate internal structures, allowing the first material 40 to be selectively positioned in high-heat regions while maintaining the overall integrity of the component. These alternative embodiments provide flexibility in optimizing heat dissipation while accommodating cost, weight, and structural constraints.

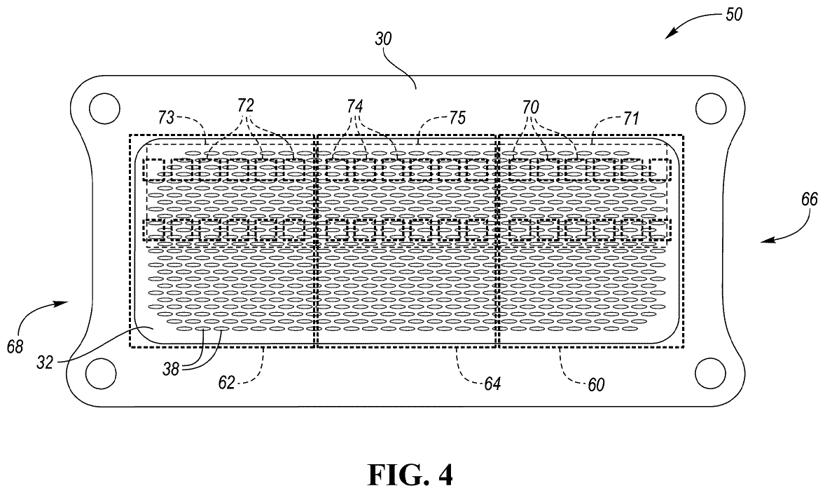

FIG. 4 illustrates a power inverter assembly 50 according to a first embodiment. The power inverter assembly 50 includes a heat sink 30 (or other heat sink 30, 30′, 30″, 30′″, etc.). A top surface or upper view of the heat sink 30 is shown in FIG. 4. Like in previous embodiments, the heat sink 30 has a base 32 having an upper surface 34 and a lower surface 36, with fins 38 extending from the upper surface 34 of the base 32. The lower surface 36 can make direct contact with a plurality of power cards, namely a first power card 60, a second power card 62, and a third power card 64. In the illustrated embodiment, the first power card 60 is located near or adjacent an inlet region 66 of the heat sink 30, and the second power card 62 is located near or adjacent an outlet region 68 of the heat sink 30. In this fashion, fluid that comes in contact with the upper surface 34 of the base 32 near the inlet region 66 will work to cool a region of heat sink 30 aligned with the first power card 60 on the bottom of the heat sink 30, and the fluid that contacts the upper surface 34 of the base 32 near the outlet region 68 will work to cool a region of the heat sink 30 aligned with the second power card 62 on the bottom of the heat sink 30. The third power card 64 is located between the first power card 60 and the second power card 62. Of course, more or less power cards can be provided, and the exact number and arrangement of power cards shown herein is only an example.

Each power card has a group of chips. For example, the first power card 60 has a firs group of chips 70, the second power card 62 has a second group of chips 72, and the third power card 64 has a third group of chips 74. The various chips can include microcontrollers or Digital Signal Processors (DSPs), driver ICs, voltage regulators, logic and control ICs, protection ICs, communication ICs, or the like. The chips may be heat-producing objects, and if not properly cooled, excess heat can cause damage and potential system failure, including thermal degradation, electrical overstress, solder joint failures, performance degradation, and the like.

The fins 38 can be spread all across a majority of the upper surface 34 on an opposite side of the heat sink 30 from the chips so as to include a first group or subset of fins 71 generally aligned with the first group of chips 70, a second group of fins 73 generally aligned with the second group of chips 72, and a third group of fins 75 generally aligned with the third group of chips 74.

Assuming fluid travels from the inlet 66 to the outlet 68, the second group of fins 73 (and thereby the second group of chips 72) might be subject to less efficient heat transfer due to the fluid increasing in temperature as it travels from inlet 66 to outlet 68 (e.g., right to left in FIG. 4). As the fluid travels over the heat sink 30, it first cools the heat sink in the area aligned with the first power card 60, then it cools the heat sink in the area aligned with the third power card 64, and then it finally cools the heat sink in the area aligned with the second power card 62. This can cause inefficient heat transfer, particularly in the area of the heat sink 30 aligned with the second power card 62.

Therefore, according to an embodiment, the first material 40 is provided only in the regions of the heat sink 30 aligned with the second power card 62 (e.g., an area of the heat sink having the second group of fins 73). In such embodiments, the first material 40 can be provided to the base 32 and/or the fins 38 in the second group of fins 73 as described with reference to FIGS. 2-3C. For example, the base 32 in the region of the second power card 62 can be provided with the first material 40 while the base 32 in the regions of the first and third power cards is not provided with the first material. Or, in other embodiments, at least some of the fins within the second group of fins 73 are provided with the first material 40 while none of the fins in the first group of fins 71 or third group of fins 75 are provided with the first material 40.

In the described embodiments, the heat sink includes at least one first region comprising the first material, which has a relatively higher thermal conductivity, and at least one second region that is substantially free of the first material. As used herein, a region that is “substantially free” of the first material (or similar language) does not necessarily require the complete absence of the first material. Rather, it means that any presence of the first material in that region is in an amount insufficient to meaningfully affect the thermal conductivity characteristics of that region. For example, trace amounts or incidental presence of the first material due to manufacturing processes, diffusion, or minor impurities are contemplated within the scope of the invention, so long as such presence does not significantly alter the intended thermal performance of the second region. This ensures that the functional distinction between the first region and the second region is maintained.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A heat sink for a power inverter assembly in a motor vehicle, the heat sink comprising:
a base having a lower surface and an opposing upper surface, wherein the lower surface contacts a heat-generating device; and
a plurality of fins extending from the opposing upper surface of the base;
wherein each fin in a first subset of the plurality of fins is made of a first material and a second material, wherein the first material has a higher thermal conductivity than the second material; and
wherein each fin in a second subset of the plurality of fins is made of the second material and is substantially free of the first material.

2. The heat sink of claim 1, wherein the first subset of fins is vertically aligned with the heat-generating device.

3. The heat sink of claim 1, wherein fluid flows from an inlet region of the heat sink to an outlet region of the heat sink, wherein the first subset of fins is located at the outlet region of the heat sink, and wherein the second subset is located at the inlet region of the heat sink.

4. The heat sink of claim 1, wherein the first subset of the plurality of fins includes a first fin and a second fin, wherein the first fin includes more of the first material than the second fin.

5. The heat sink of claim 4, wherein the first fin is located closer to an outlet region of the heat sink than the second fin is.

6. The heat sink of claim 1, wherein the base includes the first material in a location aligned with the first subset of fins.

7. The heat sink of claim 1, wherein the base includes the first material in a location aligned with the second subset of fins.

8. The heat sink of claim 1, wherein the first material extends from the upper surface of the base and partially toward an upper surface of the fin, and wherein the base is substantially free of the first material.

9. The heat sink of claim 1, wherein each fin in a third subset of the plurality of fins is made of the first material and is substantially free of the second material.

10. A heat sink for a power inverter assembly in a motor vehicle, the heat sink comprising:
a base having a lower surface and an opposing upper surface; and
a plurality of fins extending from the opposing upper surface of the base, wherein the plurality of fins includes a first subset of fins and a second subset of fins;
wherein each fin in the first subset of fins is made of a first material and a second material, wherein the first material has a higher thermal conductivity than the second material; and
wherein each fin in the second subset of fins is made of the second material and is substantially free of the first material.

11. The heat sink of claim 10, wherein the first subset of fins is vertically aligned with a heat-generating device that contacts the lower surface of the base.

12. The heat sink of claim 11, wherein the heat sink includes an inlet region and an outlet region, wherein fluid flows from an inlet region of the heat sink to an outlet region of the heat sink, wherein the first subset of fins is located at the outlet region of the heat sink, and wherein the second subset is located at the inlet region of the heat sink.

13. The heat sink of claim 12, wherein the first subset of the plurality of fins includes a first fin and a second fin, wherein the first fin includes more of the first material than the second fin.

14. The heat sink of claim 13, wherein the first fin is located closer to the outlet region of the heat sink than the second fin is.

15. The heat sink of claim 10, wherein the base includes the first material in a location aligned with the first subset of fins.

16. The heat sink of claim 15, wherein the first material extends continuously from the location aligned with the first subset of fins and into the first subset of fins.

17. The heat sink of claim 10, wherein the base includes the first material in a location aligned with the second subset of fins.

18. A power inverter assembly comprising:
a heat-generating device; and
a heat sink having:
a base having a lower surface and an opposing upper surface, wherein a region of the lower surface contacts the heat-generating device; and
a plurality of fins extending from the opposing upper surface of the base, wherein a first subset of fins are aligned with the region of the lower surface, and wherein a second subset of fins are not aligned with the region of the lower surface;
wherein at least some of the fins within the first subset of fins are made of a first material and a second material, wherein the first material has a higher thermal conductivity than the second material;
wherein at least some of the fins within the second subset of fins are made of the second material and are substantially free of the first material; and
wherein a portion of the base aligned with the region of the lower surface is made of the second material and is substantially free of the first material.

19. The power inverter assembly of claim 18, wherein fluid flows from an inlet region of the heat sink to an outlet region of the heat sink, wherein the first subset of fins is located at the outlet region of the heat sink, and wherein the second subset is located at the inlet region of the heat sink.

20. The power inverter assembly of claim 18, wherein some of the fins within the first subset of fins have an amount of the first material that differs from other fins within the first subset of fins.
